(19) United States
(12) Patent Application Publication
(10) Pub. No.: US 2021/0378122 A1
(43) Pub. Date: Dec. 2, 2021

(54) MOUNT CAGE FOR DISK DRIVE

(71) Applicants: Inventec (Pudong) Technology Corporation, Shanghai (CN); INVENTEC CORPORATION, Taipei (TW)

(72) Inventor: Jia-Bin WANG, Shanghai (CN)

(21) Appl. No.: 16/899,772

(22) Filed: Jun. 12, 2020

(30) Foreign Application Priority Data
May 28, 2020 (CN) 202010469187.5

(51) Int. Cl. H05K 7/14; H05K 7/16; H05K 5/02; G11B 33/04

(52) U.S. Cl. CPC H05K 7/1424; H05K 7/16; G11B 33/0411; H05K 5/023; H05K 5/0286

(57) ABSTRACT

A mount cage configured to mount disk drive to rack and including first cage part, second cage part, first positioning pillar and second positioning pillar. First cage part includes first plate portion, second plate portion, and third plate portion. Second plate portion and third plate portion stand on same side of first plate portion and spaced apart from each other. Second cage part includes fourth plate. Fourth plate is pivotally connected to a side of second plate portion located away from first plate portion to be detachably engaged with a side of third plate portion located away from first plate portion. First plate portion, second plate portion, third plate portion, and fourth plate together form accommodation space and two apertures connected to accommodation space. First positioning pillar is fixed in first positioning hole of disk drive. Second positioning pillar is fixed in second positioning hole of disk drive.

### CROSS-REFERENCE TO RELATED APPLICATIONS

This non-provisional application claims priority under 35 U.S.C. § 119(a) on Patent Application No(s) 202010469187.5. filed in China, on May 28, 2020, the entire contents of which are hereby incorporated by reference.

### BACKGROUND OF THE INVENTION

### Technical Field of the Invention

The invention relates to a mount cage, more particularly to a mount cage for a disk drive.

### Description of the Related Art

With the development of the cloud technology, servers need to have a certain number of disk drives to obtain the required storage capacity. Also, for the purposes of removing the damaged disk drive without affecting the operations of other disk drives and easily adjusting the quantity of the disk drives according to actual requirements, a typical server chassis would have cages or frames for accommodating each disk drives, such that the disk drive can be easily installed or removed from the server chassis and therefore facilitate the maintenance process of the disk drives.

However, the cages occupy a certain amount of the internal space of the server chassis and thus reduce the space available for the disk drives. As a result, the quantity of the disk drives that the server chassis can accommodate is reduced. In addition, the cages may block the air channels that were supposed for the waste heat generated by the disk drive and therefore result in a rise of temperature of the disk drive. Thus, there is a demand for a disk drive cage that occupies less internal space of server and does not affect the heat dissipation of the disk drives.

### SUMMARY OF THE INVENTION

The invention is to provide a mount cage making the server chassis able to accommodate more disk drives while preventing affecting the heat dissipation of the disk drive.

One embodiment of this invention provides a mount cage configured to mount a disk drive to a rack and including a first cage part, a second cage part, a first positioning pillar and a second positioning pillar. The first cage part includes a first plate portion, a second plate portion, and a third plate portion. The second plate portion and the third plate portion stand on a same side of the first plate portion and are spaced apart from each other. The second cage part includes a fourth plate. The fourth plate is pivotally connected to a side of the second plate portion that is located away from the first plate portion so as to be detachably engaged with a side of the third plate portion that is located away from the first plate portion. The first plate portion, the second plate portion, the third plate portion, and the fourth plate together form an accommodation space and two apertures connected to the accommodation space. The first positioning pillar is fixed to the first plate portion and is located between the first plate portion and the fourth plate. The first positioning pillar is configured to be fixed in a first positioning hole of the disk drive. The second positioning pillar is fixed to the fourth plate and is located between the first plate portion and the fourth plate. The second positioning pillar is configured to be fixed in a second positioning hole of the disk drive.

According to the mount cage discussed in the above embodiments, the first plate portion, the second plate portion, the third plate portion, the fourth plate together form the accommodation space and the two apertures connected to the accommodation space, and thus the mount cage only covers the side surface of the disk drive but does not cover the top surface and the bottom surface of the disk drive. Also, the first positioning pillars located on the first plate portion and the second positioning pillars located on the fourth plate are respectively fixed in the first positioning holes and the second positioning holes of the disk drive. In this way, pairs of the disk drive and the mount cage that are fixed to each other can be stacked in a dense manner, such that the space occupied by the mount cage is reduced and more disk drives are allowed to be accommodated in the server chassis.

Moreover, since the top surface and the bottom surface of the disk drive are respectively exposed by the apertures, the heat generated by the disk drive can be directly removed by the airflow flowing through the apertures, such that the mount cage is prevented from affecting the heat dissipation of the disk drive.

### BRIEF DESCRIPTION OF THE DRAWINGS

The present invention will become more fully understood from the detailed description given hereinbelow and the accompanying drawings which are given by way of illustration only and thus are not limitative of the present invention and wherein:

FIG. 1 is a perspective view showing that a plurality of disk drives are mounted on a rack via a plurality of mount cages according to an embodiment of the invention;

FIG. 2 is a perspective view of one of the mount cages in FIG. 1;

FIG. 3 is an exploded view of the mount cage in FIG. 2;

FIG. 4 is a side view of the mount cage in FIG. 2;

FIG. 5 is a partially enlarged side cross-sectional view showing that an engagement component is engaged in an engagement hole of a handle portion;

FIG. 6 is a partially enlarged side cross-sectional view showing that the engagement component is detached from the engagement hole of the handle portion; and

FIG. 7 is a partially enlarged exploded view of one of the disk drive, the rack and one of the mount cage in FIG. 1.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

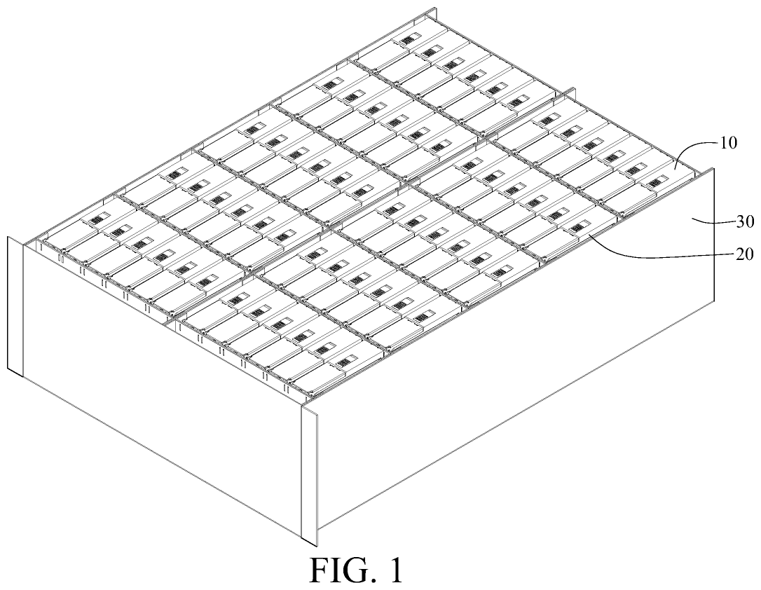

Please refer to FIG. 1, there is shown a perspective view showing that a plurality of disk drives are mounted on a rack via a plurality of mount cages according to an embodiment of the invention.

This embodiment provides a plurality of mount cages 10 that are respectively configured to mount a plurality of disk drives 20 on the rack 30. Noted that, for the purpose of illustration, only the detail of one of the mount cages 10 will be described below.

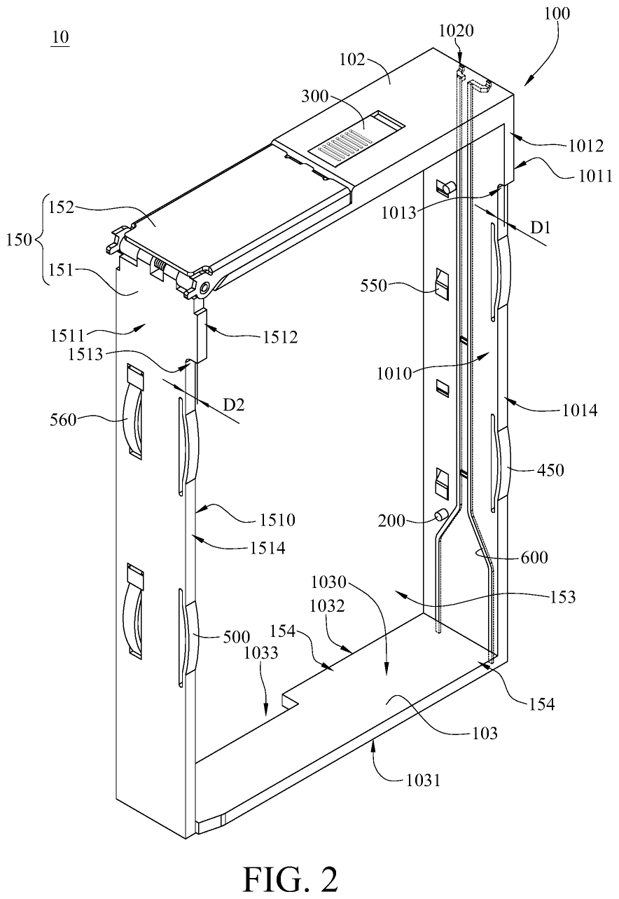

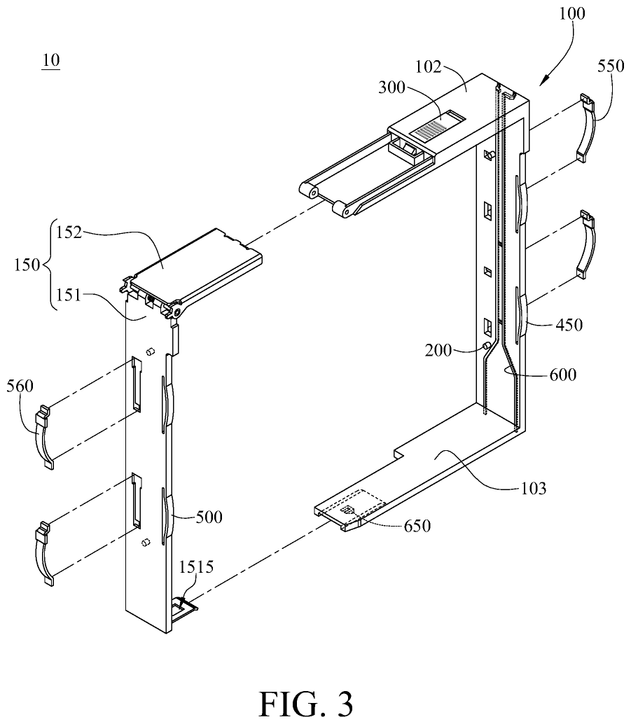

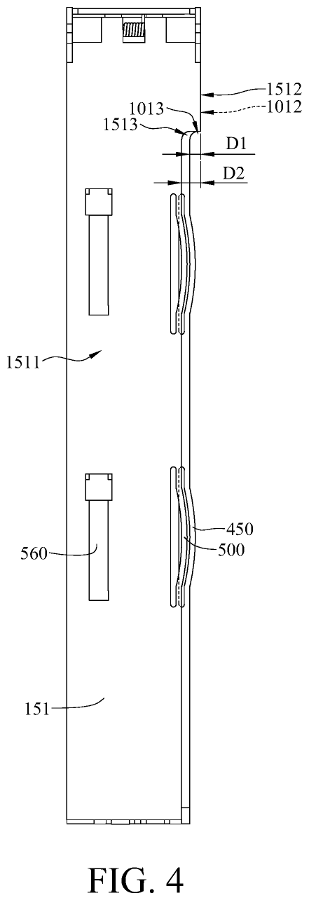

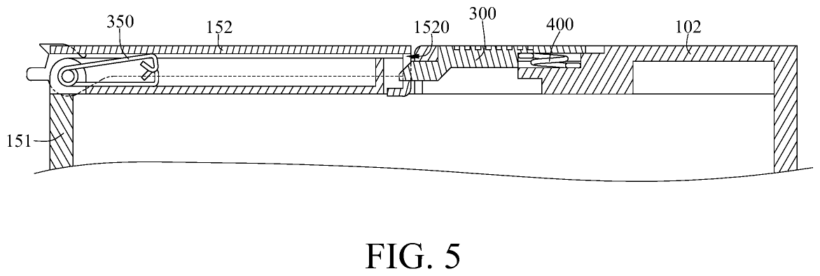

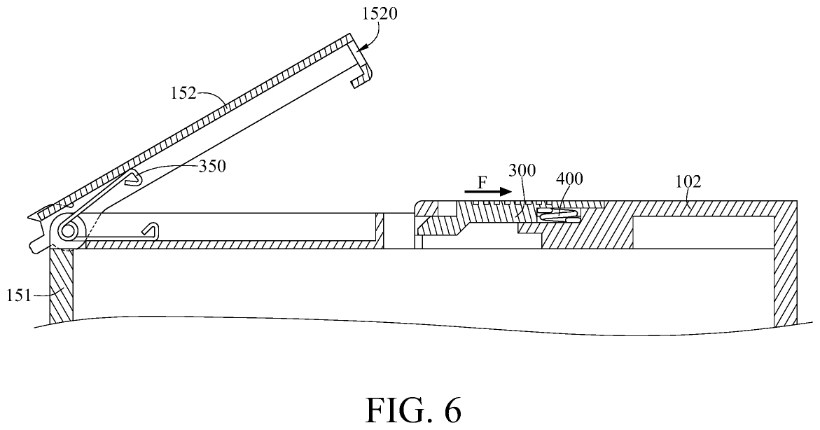

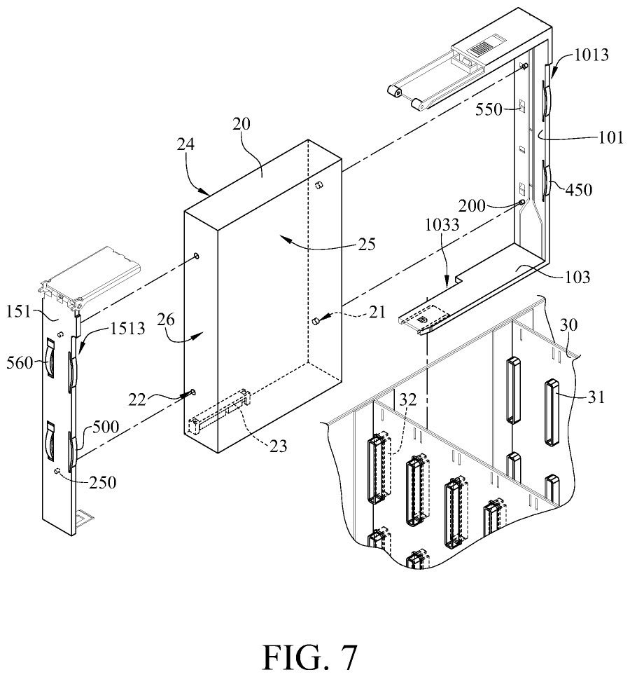

Please refer to FIG. 2 to FIG. 7, where FIG. 2 is a perspective view of one of the mount cages in FIG. 1, FIG. 3 is an exploded view of the mount cage in FIG. 2, FIG. 4 is a side view of the mount cage in FIG. 2, FIG. 5 is a partially enlarged side cross-sectional view showing that the engagement component is detached from the engagement hole of the handle portion, FIG. 6 is a partially enlarged exploded view of the disk drive, the cage and the mount cage in FIG. 1, and FIG. 7 is a partially enlarged exploded view of one of the disk drive, the cage and one of the mount cage in FIG. 1.

In this embodiment, the mount cage 10 includes a first cage part 100, a second cage part 150, two first positioning pillars 200, two second positioning pillars 250, an engagement component 300, a first elastic component 350, a second elastic component 400, two first elastic damping plates 450, two second elastic damping plates 500, two first electrically conductive elastic plates 550, two second electrically conductive elastic plates 560, a light guide assembly 600, and an engagement protrusion 650.

The first cage part 100 includes a first plate portion 101, a second plate portion 102, and a third plate portion 103. The second plate portion 102 and the third plate portion 103 stand on the same side of the first plate portion 101 and are spaced apart from each other.

In this embodiment, the first plate portion 101 has a first inner surface 1010, a first outer surface 1011, a first side surface 1012, and a first engagement groove 1013. The first inner surface 1010 faces away from the first outer surface 1011. The first side surface 1012 connects the first inner surface 1010 and the first outer surface 1011. The first engagement groove 1013 is located on the first side surface 1012 and penetrates through the first inner surface 1010 and the first outer surface 1011. Also, the first engagement groove 1013 has a first depth D1 relative to the first side surface 1012.

However, the first engagement groove 1013 is optional. In other embodiments, the first plate portion may omit the first engagement groove 1013.

In this embodiment, the third plate portion 103 has a second inner surface 1030, a second outer surface 1031, a second side surface 1032 and a cut-off portion 1033. The second inner surface 1030 faces away from the second outer surface 1031. The second side surface 1032 connects the second inner surface 1030 and the second outer surface 1031. The cut-off portion 1033 is located on the second side surface 1032 and penetrates through the second inner surface 1030 and the second outer surface 1031.

However, the cut-off portion 1033 is optional. In other embodiments, the third plate portion may omit the cut-off portion 1033.

The second cage part 150 includes a fourth plate 151 and a handle portion 152. The fourth plate 151 is pivotally connected to a side of the second plate portion 102 that is located away from the first plate portion 101 so as to be detachably engaged with a side of the third plate portion 103 that is located away from the first plate portion 101. The first plate portion 101, the second plate portion 102, the third plate portion 103 and the fourth plate 151 together form an accommodation space 153 and two apertures 154 connected to the accommodation space 153. The handle portion 152 has an engagement hole 1520 and is pivotally connected to the fourth plate 151 and therefore is movable between a closed position and an opened position.

In this embodiment, the fourth plate 151 has a third inner surface 1510, a third outer surface 1511, a third side surface 1512, and a second engagement groove 1513. The third inner surface 1510 faces away from the third outer surface 1511. The third side surface 1512 connects the third inner surface 1510 and the third outer surface 1511. The second engagement groove 1513 is located on the third side surface 1512 and penetrates through the third inner surface 1510 and the third outer surface 1511. Also, the second engagement groove 1513 has a second depth D2 relative to the third side surface 1512. In addition, the first depth D1 of the first engagement groove 1013 is different from the second depth D2 of the second engagement groove 1513, but the invention is not limited thereto. In other embodiments, the first depth of the first engagement groove relative to the first side surface of the first plate portion may be the same as the second depth of the second engagement groove relative to the third side surface of the fourth plate.

However, the second engagement groove 1513 is optional. In other embodiments, the fourth plate may omit the second engagement groove 1513.

The first positioning pillars 200 are fixed to the first plate portion 101 and are located between the first plate portion 101 and the fourth plate 151. The second positioning pillars 250 are fixed to the fourth plate 151 and are located between the first plate portion 101 and the fourth plate 151.

Quantities of the first positioning pillars 200 and the second positioning pillars 250 are not restricted. In other embodiments, the mount cage may also include one first positioning pillar and one second positioning pillar.

Furthermore, please refer to FIG. 5 and FIG. 6. The engagement component 300 is movably disposed on the second plate portion 102. The handle portion 152 has an engagement hole 1520. The handle portion 152 is pivotally connected to the fourth plate 151 and therefore is movable between a closed position and an opened position. As the handle portion 152 is in the closed position, the engagement component 300 is detachably engaged in the engagement hole 1520 of the handle portion 152.

Two opposite ends of the first elastic component 350 are respectively fixed to the handle portion 152 and the second plate portion 102. Two opposite ends of the second elastic component 400 are respectively fixed to the engagement component 300 and the second plate portion 102. In one embodiment, the first elastic component 350 and the second elastic component 400 are, for example, torsion springs.

As shown in FIG. 5, when the engagement component 300 is engaged in the engagement hole 1520 of the handle portion 152, the second elastic component 400 is able to prevent the engagement component 300 from being detached from the engagement hole 1520. When the engagement component 300 is engaged in the engagement hole 1520 of the handle portion 152, the handle portion 152 is maintained in the closed position and the first elastic component 350 is compressed.

As shown in FIG. 6, when the engagement component 300 is moved along a detaching direction F, the engagement component 300 is detached from the engagement hole 1520 of the handle portion 152. As the engagement component 300 is detached from the engagement hole 1520 of the handle portion 152, the first elastic component 350 will be released to force the handle portion 152 to move towards the opened position. so that the handle portion 152 can be held in a convenient manner.

However, the first elastic component 350 and the second elastic component 400 are optional. In other embodiments, the mount cage may not include the first elastic component 350 and the second elastic component 400.

In addition, the engagement component 300 is optional. In other embodiments, the mount cage may not include the engagement component 300, and other type of fasteners such as Velcro is used to fixed the handle portion in the closed position.

Please refer back to FIG. 2 and FIG. 4, the first elastic damping plates 450 are integrally formed with the first plate portion 101 and are located on a first inner wall surface 1014 of the first plate portion 101 that forms the first engagement groove 1013. The second elastic damping plates 500 are integrally formed with the fourth plate 151 and are located on a second inner wall surface 1514 of the fourth plate 151 that forms the second engagement groove 1513.

However, the mount frame 10 is not limited to include the two first elastic damping plates 450 and the two second elastic damping plates 500. In other embodiments, the mount frame may only include one first elastic damping plate and one second elastic damping plate. In still other embodiments, the mount frame may not include the first elastic damping plate 450 and the second elastic damping plate 500.

As shown in FIG. 2, the first electrically conductive elastic plates 550 protrude from a side of the first plate portion 101 that is located away from the fourth plate 151, and a part of each first electrically conductive elastic plate 550 is located between the first plate portion 101 and the fourth plate 151.

As shown in FIG. 2, the second electrically conductive elastic plates 560 protrude from a side of the fourth plate 151 that is located away from the first plate portion 101, and a part of each second electrically conductive elastic plate 560 is located between the first plate portion 101 and the fourth plate 151.

However, the mount frame 10 is not limited to include the two first electrically conductive elastic plates 550 and the two second electrically conductive elastic plates 560. In other embodiments, the mount cage may include one first electrically conductive elastic plate and one second electrically conductive elastic plate. In still other embodiments, the mount cage may not include the first electrically conductive elastic plate and the second electrically conductive elastic plate.

As shown in FIG. 2, the second plate portion 102 has two openings 1020. The light guide assembly 600 is fixed on the first plate portion 101 and exposed by the openings 1020. However, the light guide assembly 600 is optional. In other embodiments, the mount cage may not include the light guide assembly 600. In the embodiments where the mount cage does not include the light guide assembly 600, the second plate portion may not have the aforementioned openings 1020.

As shown in FIG. 3, the fourth plate 151 has an engagement hole 1515. The engagement protrusion 650 protrudes from the third plate portion 103 and is detachably engaged in the engagement hole 1515, such that the fourth plate 151 is detachably engaged with the third plate portion 103. However, the engagement protrusion 650 is optional. In other embodiments, the mount cage may not include the engagement protrusion. In the embodiments where the mount cage does not include the engagement protrusion, the fourth plate may not have the aforementioned engagement hole.

Please refer to FIGS. 1, 2 and 7, the disk drive 20 can be accommodated in the accommodation space 153. To do so, the first positioning pillars 200 are respectively configured to be fixed in the first positioning holes 21 of the disk drive 20, the second positioning pillars 250 are respectively configured to be fixed in the second positioning holes 22 of the disk drive 20, and then a connector 23 of the disk drive 20 will be located at the cut-off portion 1033 of the third plate portion 103 and a top surface 24 and a bottom surface 25 of the disk drive 20 will be respectively exposed by the apertures 154. As such, the mount cage 10 only covers a side surface 26 of the disk drive 20 connecting the top surface 24 and the bottom surface 25 but does not cover the top surface 24 and the bottom surface 25 of the disk drive 20.

As the disk drive 20 is installed in the mount cage 10, two opposite sides of the first electrically conductive elastic plate 550 are respectively configured to be in contact with the disk drive 20 and the rack 30, and two opposite sides of the second electrically conductive elastic plate 560 are respectively configured to be in contact with the disk drive 20 and the rack 30.

The first engagement grooves 1013 of the mount cages 10 are respectively configured to be engaged with a plurality of first projections 31 located on the rack 30. The second engagement grooves 1513 of the mount cages 10 are respectively configured to be engaged with a plurality of second projections 32 located on the rack 30. Thus, the mount cages 10 can be fixed in position on the rack 30. In addition, the first projections 31 of the disk drive 20 respectively press against the first elastic damping plates 450 so that the first elastic damping plate 450 can absorb the impact from the first projections 31. The second projections 32 of the disk drive 20 respectively press against the second elastic damping plates 500 so that the second elastic damping plates 500 can absorb the impact from the second projections 32. Since the first depth D1 of the first engagement groove 1013 is different from the second depth D2 of the second engagement groove 1513, the first engagement groove 1013 cannot be engaged with the second projection 32 and the second engagement groove 1513 cannot be engaged with the first projection 31, thereby achieving error-proof function.

According to the mount cage discussed in the above embodiments, the first plate portion, the second plate portion, the third plate portion, the fourth plate together form the accommodation space and the two apertures connected to the accommodation space, and thus the mount cage only covers the side surface of the disk drive but does not cover the top surface and the bottom surface of the disk drive. Also, the first positioning pillars located on the first plate portion and the second positioning pillars located on the fourth plate are respectively fixed in the first positioning holes and the second positioning holes of the disk drive. In this way, pairs of the disk drive and the mount cage that are fixed to each other can be stacked in a dense manner, such that the space occupied by the mount cage is reduced and more disk drives are allowed to be accommodated in the server chassis.

Moreover, since the top surface and the bottom surface of the disk drive are respectively exposed by the apertures, the heat generated by the disk drive can be directly removed by the airflow flowing through the apertures, such that the mount cage is prevented from affecting the heat dissipation of the disk drive.

It will be apparent to those skilled in the art that various modifications and variations can be made to the present invention. It is intended that the specification and examples be considered as exemplary embodiments only, with a scope of the invention being indicated by the following claims and their equivalents.

What is claimed is:

1. A mount cage, configured to mount a disk drive to a rack, the mount cage comprising:
a first cage part, comprising a first plate portion, a second plate portion, and a third plate portion, the second plate portion and the third plate portion standing on a same side of the first plate portion and spaced apart from each other;
a second cage part, comprising a fourth plate, the fourth plate pivotally connected to a side of the second plate portion that is located away from the first plate portion so as to be detachably engaged with a side of the third plate portion that is located away from the first plate portion, the first plate portion, the second plate portion, the third plate portion, and the fourth plate together forming an accommodation space and two apertures connected to the accommodation space;
a first positioning pillar, fixed to the first plate portion and located between the first plate portion and the fourth plate, the first positioning pillar configured to be fixed in a first positioning hole of the disk drive; and
a second positioning pillar, fixed to the fourth plate and located between the first plate portion and the fourth plate, the second positioning pillar configured to be fixed in a second positioning hole of the disk drive.

2. The mount cage according to claim 1, further comprising an engagement component, wherein the second cage part further comprises a handle portion, the engagement component is movably disposed on the second plate portion, the handle portion has an engagement hole, and the handle portion is pivotally connected to the fourth plate so that the engagement component is detachably engaged in the engagement hole.

3. The mount cage according to claim 2, further comprising a first elastic component and a second elastic component, wherein two opposite ends of the first elastic component are respectively fixed to the handle portion and the second plate portion, two opposite ends of the second elastic component are respectively fixed to the engagement component and the second plate portion.

4. The mount cage according to claim 1, wherein the first plate portion has a first inner surface, a first outer surface, a first side surface and a first engagement groove, the first inner surface faces away from the first outer surface, the first side surface connects the first inner surface and the first outer surface, the first engagement groove is located on the first side surface and penetrates through the first inner surface and the first outer surface so as to be configured to be engaged with a first projection located on the rack, the fourth plate has a second inner surface, a second outer surface, a second side surface and a second engagement groove, the second inner surface faces away from the second outer surface, the second side surface connects the second inner surface and the second outer surface, the second engagement groove is located on the second side surface and penetrates through the second inner surface and the second outer surface so as to be configured to be engaged with a second projection located on the rack.

5. The mount cage according to claim 4, wherein a first depth of the first engagement groove relative to the first side surface of the first plate portion is different from a second depth of the second engagement groove relative to the second side surface of the fourth plate.

6. The mount cage according to claim 4, further comprising a first elastic damping plate and a second elastic damping plate, wherein the first elastic damping plate is integrally formed with the first plate portion and is located on a first inner wall surface of the first plate portion that forms the first engagement groove, the second elastic damping plate is integrally formed with the fourth plate and is located on a second inner wall surface of the fourth plate that forms the second engagement groove.

7. The mount cage according to claim 1, further comprising an electrically conductive elastic plate, wherein the electrically conductive elastic plate protrudes from a side of the fourth plate that is located away from the first plate portion so as to be configured to be in contact with the rack, and a part of the electrically conductive elastic plate is located between the first plate portion and the fourth plate to be configured to be in contact with the disk drive.

8. The mount cage according to claim 1, further comprising a light guide assembly, the second plate portion having two openings, and the light guide assembly fixed to the first plate portion and exposed by the two opening.

9. The mount cage according to claim 1, further comprising an engagement protrusion, wherein the fourth plate has an engagement hole, the engagement protrusion protrudes from the third plate portion and is detachably engaged in the engagement hole so that the fourth plate is detachably engaged with the third plate portion.

10. The mount cage according to claim 1, wherein the third plate portion has a first inner surface, a first outer surface, a first side surface and a cut-off portion, the first inner surface faces away from the first outer surface, the first side surface connects the first inner surface and the first outer surface, the cut-off portion is located on the first side surface and penetrates through the first inner surface and the first outer surface, and a connector of the disk drive is configured to be disposed through the cut-off portion.
